(19) United States
(12) Patent Application Publication
(10) Pub. No.: US 2024/0096809 A1
(43) Pub. Date: Mar. 21, 2024

(54) MICROELECTRONIC ASSEMBLIES WITH MIXED COPPER AND SOLDER INTERCONNECTS HAVING DIFFERENT THICKNESSES

(71) Applicant: Intel Corporation, Santa Clara, CA (US)

(72) Inventors: Hiroki Tanaka, Gilbert, AZ (US); Robert Alan May, Chandler, AZ (US); Onur Ozkan, Scottsdale, AZ (US); Ali Lehaf, Chandler, AZ (US); Steve Cho, Chandler, AZ (US); Gang Duan, Chandler, AZ (US); Jieping Zhang, Mesa, AZ (US); Rahul N. Manepalli, Chandler, AZ (US); Ravindranath Vithal Mahajan, Chandler, AZ (US); Hamid Azimi, Paradise Valley, AZ (US)

(73) Assignee: Intel Corporation, Santa Clara, CA (US)

(21) Appl. No.: 17/932,624

(22) Filed: Sep. 15, 2022

(51) Int. Cl. H01L 23/538; H01L 21/48; H01L 23/00; H01L 23/31; H01L 25/00; H01L 25/065

(52) U.S. Cl. CPC H01L 23/5386; H01L 21/4857; H01L 23/3121; H01L 23/5383; H01L 24/13; H01L 24/14; H01L 24/16; H01L 24/19; H01L 24/20; H01L 25/0652; H01L 25/0655; H01L 25/50; H01L 24/32; H01L 2224/13082; H01L 2224/1403; H01L 2224/16238; H01L 2224/19; H01L 2224/211; H01L 2224/2201; H01L 2224/32225

(57) ABSTRACT

Microelectronic assemblies, related devices and methods, are disclosed herein. In some embodiments, a microelectronic assembly may include a substrate having a surface including first conductive contacts and second conductive contacts, wherein the first conductive contacts have a first thickness and the second conductive contacts have a second thickness different than the first thickness; a first microelectronic component having third conductive contacts, wherein respective ones of the third conductive contacts are coupled to respective ones of the first conductive contacts by first interconnects, wherein the first interconnects include solder having a thickness between 2 microns and 35 microns; and a second microelectronic component having fourth conductive contact, wherein respective ones of the fourth conductive contacts are coupled to respective ones of the second conductive contacts by second interconnects, wherein the second interconnects include solder having a thickness between 5 microns and 50 microns.

### GOVERNMENT LICENSE RIGHTS

This invention was made with Government support under Agreement No. HR00111830002 awarded by the United States Department of Defense. The Government has certain rights in the invention.

### BACKGROUND

Integrated circuit (IC) devices (e.g., dies) are typically coupled together in a multi-die IC package to integrate features or functionality and to facilitate connections to other components, such as package substrates. IC packages may include a bridge component or an embedded multi-die interconnect bridge (EMIB) for coupling two or more IC dies.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIGS. 1A and 1B are side, cross-sectional views of example microelectronic assemblies, in accordance with various embodiments.

FIGS. 2A and 2B are side, cross-sectional views of other example microelectronic assemblies, in accordance with various embodiments.

FIGS. 3A and 3B are side, cross-sectional views of other example microelectronic assemblies, in accordance with various embodiments.

FIGS. 4A and 4B are side, cross-sectional views of other example microelectronic assemblies, in accordance with various embodiments.

FIGS. 5A-5K are side, cross-sectional views of various stages in an example process for manufacturing the microelectronic assembly, in accordance with various embodiments.

FIG. 6 is a flow diagram of an example process for manufacturing a microelectronic assembly, in accordance with various embodiments.

FIG. 7 is a top view of a wafer and dies that may be included in a microelectronic assembly, in accordance with any of the embodiments disclosed herein.

FIG. 8 is a cross-sectional side view of an IC device that may be included in a microelectronic assembly, in accordance with any of the embodiments disclosed herein.

FIG. 9 is a cross-sectional side view of an IC device assembly that may include a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

Microelectronic assemblies, related devices and methods, are disclosed herein. For example, in some embodiments, a microelectronic assembly may include a substrate having a surface including first conductive contacts and second conductive contacts, wherein the first conductive contacts have a first thickness and the second conductive contacts have a second thickness different than the first thickness; a first microelectronic component having third conductive contacts, wherein respective ones of the third conductive contacts are coupled to respective ones of the first conductive contacts by first interconnects, wherein the first interconnects include solder having a thickness between 2 microns and 35 microns; and a second microelectronic component having fourth conductive contact, wherein respective ones of the fourth conductive contacts are coupled to respective ones of the second conductive contacts by second interconnects, wherein the second interconnects include solder having a thickness between 5 microns and 50 microns.

As demands for high performance computing (HPC) continue to rise, heterogeneous integration (HI) has become an important performance enabler in the microelectronics industry by providing the flexibility of die disaggregation and the ability to mix and match different intellectual property (IP) blocks on different silicon nodes in a single IC package, as referred to herein as multi-die IC packages. A focus of HI scaling is to optimize interconnect density with increased bandwidth and improved power efficiency. Conventional 2.5-dimensional (2.5D) and 3-dimensional (3D) advanced packaging architectures increase planar and 3D input/output (I/O) wire/area density for higher bandwidth requirements, and enable more effective HI-based die disaggregation. Multi-die IC packages require a significant level of design for placing heterogeneous die and mixing of components to optimize system and product performance. For example, multi-die IC packages that include different silicon technology nodes and large form factor die stitching capability with a high number of bridges embedded in the package substrate require a high level of design to integrate the components together. Multi-die IC packages may also include multiple stacked die subassemblies, which enables greater computing performance, but further increases design complexity. In emerging multi-die IC packaging architectures, interconnect bump pitch between different components must be further reduced, which increases design and manufacturing complexity due to stringent on package requirements of total thickness variation (TTV) and bump thickness variation (BTV). Various ones of the embodiments disclosed herein may help reduce the cost and complexity associated with assembling multi-die IC packages relative to conventional approaches by incorporating conductive contacts with different thickness that form interconnects having different solder thicknesses to meet TTV and BTV manufacturing requirements. Further, the embodiments disclosed herein may enable flexible designs for extremely complex heterogeneous packages for future high performance computing needs, which may in result in reduced development timelines and decreased time to market.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques will exhibit rounded corners, surface roughness, and other features. It is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.” Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner. The term “circuit” means one or more passive and/or active components that are arranged to cooperate with one another to provide a desired function. The terms “substantially,” “close,” “approximately,” “near,” and “about,” generally refer to being within +/−20% of a target value (e.g., within +/−5 or 10% of a target value) based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

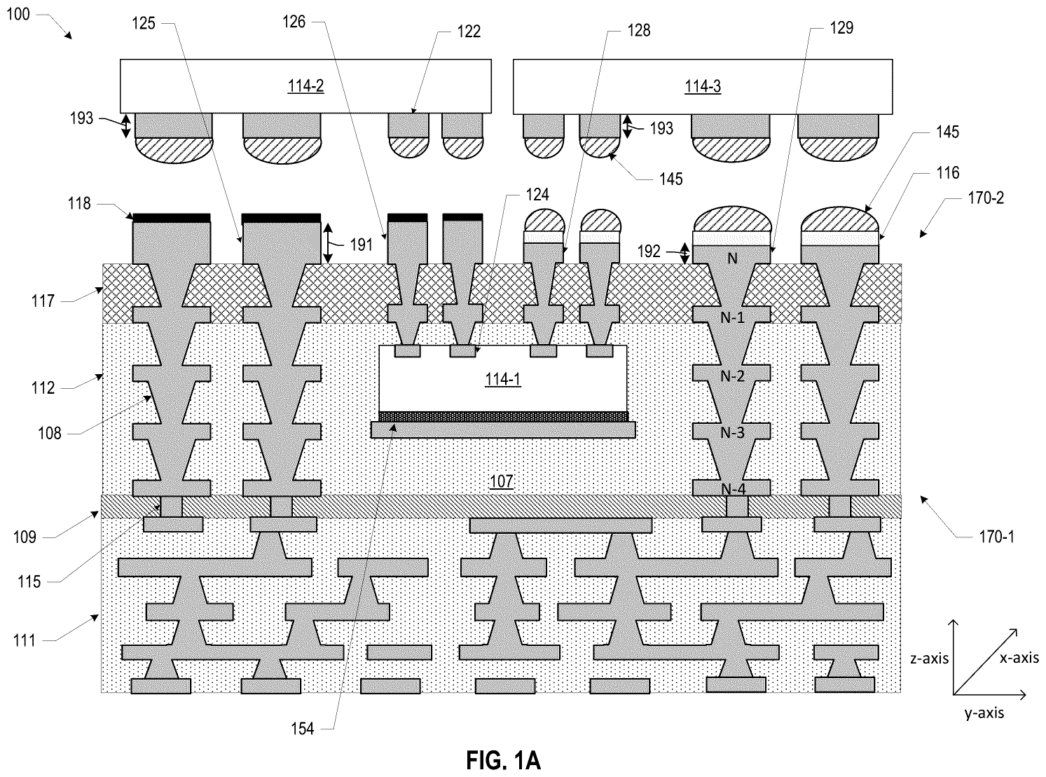

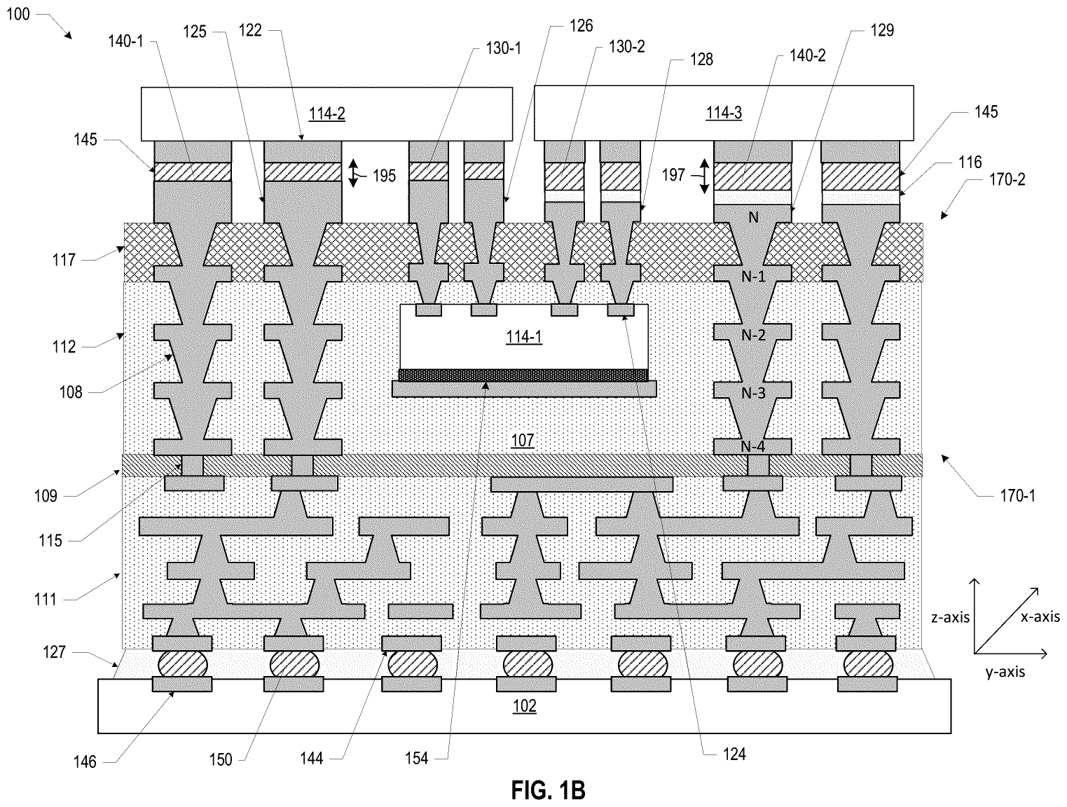

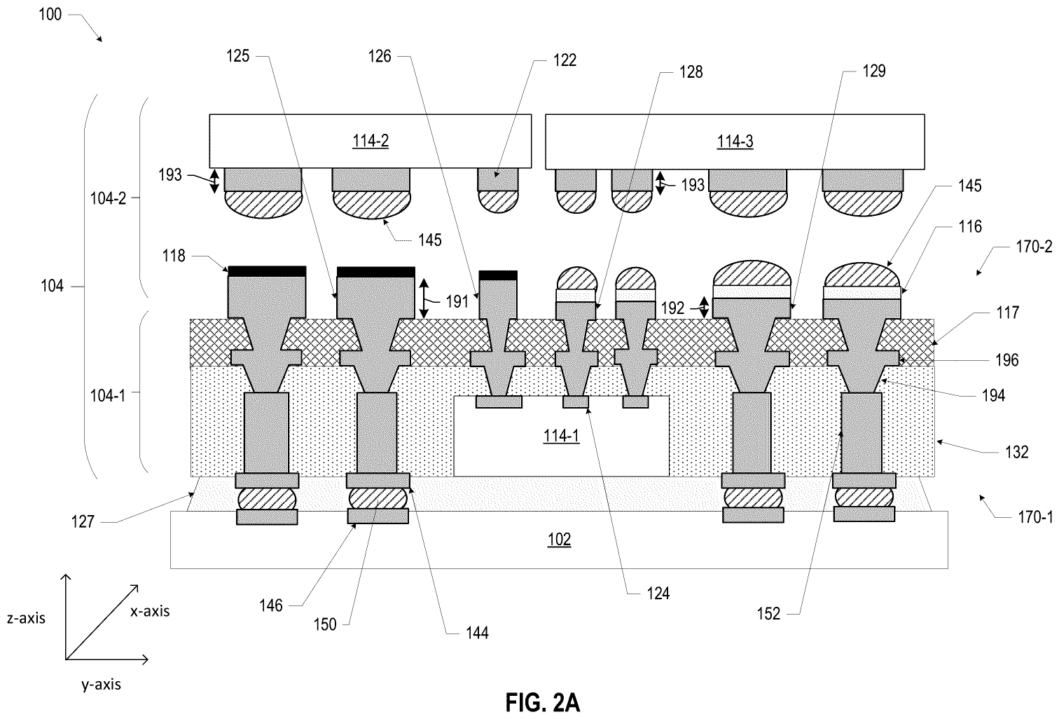

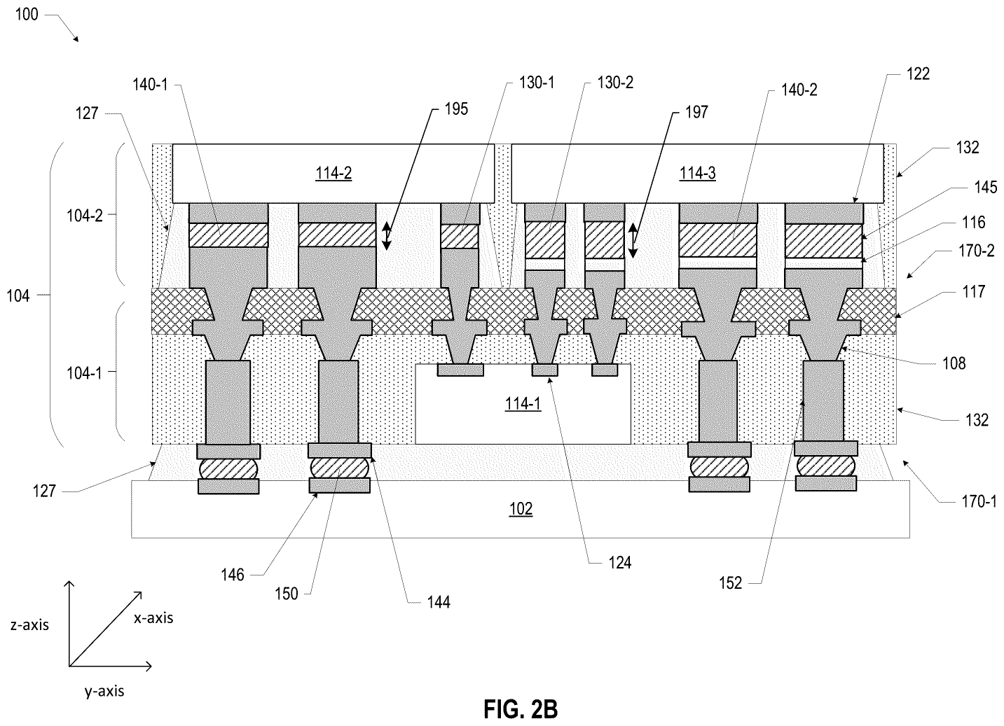

When used to describe a range of dimensions, the phrase “between X and Y” represents a range that includes X and Y. For convenience, the phrase “FIG. 1” may be used to refer to the collection of drawings of FIGS. 1A and 1B, the phrase “FIG. 2” may be used to refer to the collection of drawings of FIGS. 2A and 2B, etc. Although certain elements may be referred to in the singular herein, such elements may include multiple sub-elements. For example, “an insulating material” may include one or more insulating materials.

FIG. 1A is a side, cross-sectional view of an example microelectronic assembly, in accordance with various embodiments. The microelectronic assembly 100 may include a substrate 107 with a first surface 170-1 and an opposing second surface 170-2, the second surface 170-2 including a first conductive contact 125 and a second conductive contact 126 having a first thickness 191 and a third conductive contact 128 and a fourth conductive contact 129 having a second thickness 192 different than the first thickness 191. In some embodiments, a first thickness 191 is greater than a second thickness 192. In some embodiments, a first thickness 191 is between 5 microns and 50 microns. In some embodiments, a second thickness 192 is between 2 microns and 35 microns. In some embodiments, the first and second conductive contacts 125, 126 may include a first material 118 (e.g., a surface finish or a liner material) on a top surface, which may protect the underlying material of the conductive contact from corrosion and/or oxidation. In some embodiments, the first material 118 may include gold, palladium, nickel, an organic surface protection layer, or a combination thereof. In some embodiments, the third and fourth conductive contacts 128, 129 may include solder 145 at a top surface of the third and fourth conductive contacts 128, 129. The solder 145 may include a material with nickel or tin, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, the third and fourth conductive contacts 128, 129 may include a second material 116 (e.g., a second liner) between a top surface of the third and fourth conductive contacts 128, 129 and the solder 145. In some embodiments, a second material 116 may include nickel, copper, cobalt, iron, or a combination thereof. In some embodiments, the second material 116 may have a thickness between 1 micron and 8 microns.

As used herein, a “conductive contact” may refer to a portion of conductive material (e.g., metal) serving as an electrical interface between different components (e.g., part of a conductive interconnect); conductive contacts may be recessed in, flush with, or extending away (e.g., having a pillar shape) from a surface of a component, and may take any suitable form (e.g., a conductive pad or socket, or portion of a conductive line or via). In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The substrate 107 may include a dielectric material 112 and a conductive material 108 (e.g., lines/traces/pads and vias, as shown) with the conductive material 108 arranged in the dielectric material 112 to provide conductive pathways through the substrate 107. The dielectric material 112 in the substrate 107 may be formed in layers. In some embodiments, the dielectric material 112 may include an organic material, such as an organic buildup film. In some embodiments, the dielectric material 112 may include a ceramic, an epoxy film having filler particles therein, glass, an inorganic material, or combinations of organic and inorganic materials, for example. In some embodiments, the conductive material 108 may include a metal (e.g., copper). In some embodiments, the substrate 107 may include layers of dielectric material 112/conductive material 108, with lines/traces/pads of conductive material 108 in one layer electrically coupled to lines/traces/pads of conductive material 108 in an adjacent layer by vias of the conductive material 108 extending through the dielectric material 112. A substrate 107 including such layers may be formed using a printed circuit board (PCB) fabrication technique, for example.

A substrate 107 may include N such metal layers, where N is an integer greater than or equal to one; in the accompanying drawings, the layers are labeled in descending order from the second surface 170-2 of the substrate 107 (e.g., layer N, layer N−1, layer N−2, etc.). In particular, as shown in FIG. 1A, a substrate 107 may include five metal layers (e.g., N, N−1, N−2, N−3, and N−4). The N metal layer may include first, second, third, and fourth conductive contacts 125, 126, 128, 129 at a top surface 170-2 of the substrate 107.

A substrate 107 may further include a surface insulation material 117. The surface insulation material 117 may include a solder resist and/or other dielectric materials that may provide surface electrical insulation and may be compatible with solder-based or non-solder based interconnects, as appropriate.

Although a particular number and arrangement of layers of dielectric material 112/conductive material 108 are shown in various ones of the accompanying figures, these particular numbers and arrangements are simply illustrative, and any desired number and arrangement of dielectric material 112/conductive material 108 may be used. Further, although a particular number of layers are shown in the substrate 107 (e.g., four layers), these layers may represent only a portion of the substrate 107, for example, further layers may be present (e.g., layers N−5, N−6, N−7, etc.). As shown in FIG. 1A, the substrate 107 may further include a core 109 with through core vias 115 and further layers 111 may be present below the core 109. In some embodiments, a substrate 107 may not include a core 109 and/or further layers 111. The core 109 may be formed of any suitable material, including glass, a fiber-reinforced epoxy, an organic dielectric material, such as an epoxy, or a phenolic resin or polyimide resin reinforced with glass, aramid, or nylon.

The substrate 107 may further include a bridge die 114-1 surrounded by the dielectric material 112 of the substrate 107 (e.g., the bridge die 114-1 may be embedded in the dielectric material 112 of the substrate 107). The bridge die 114-1 may include a bottom surface (e.g., the surface facing towards the first surface 170-1) and an opposing top surface (e.g., the surface facing towards the second surface 170-2) with conductive contacts 124. In some embodiments, a pitch of the conductive contacts 124 on the bridge die 114-1 maybe between 5 microns and 120 microns. As used herein, pitch is measured center-to-center (e.g., from a center of a conductive contact to a center of an adjacent conductive contact). In some embodiments, as shown in FIG. 1A, the bridge die 114-1 may be mechanically coupled to a conductive material 108 (or a dielectric material at a bottom surface the substrate 107 by an adhesive 154 (e.g., a die-attach film (DAF)). The conductive contacts 124 of the bridge die 114-1 may be electrically coupled to second conductive contacts 126 and third conductive contacts 128 at the second surface 170-2 of the substrate 107 by conductive pathways (e.g., conductive material 108) through the substrate 107. In some embodiments, the bridge die 114-1 may be a single-sided die, as shown in FIG. 1A, in the sense that the bridge die 114-1 includes conductive contacts 124 on a top or bottom surface. In some embodiments, the bridge die 114-1 may be a double-sided die having conductive contacts on top and bottom surfaces (not shown). In such instances, the bridge die 114-1 may further include through-substrate vias (TSVs) coupling respective top and bottom conductive contacts. As used herein, the terms “bridge die,” “interconnect component,” and similar variations may be used interchangeably.

As shown in FIG. 1A, the top surface 170-2 of the substrate 107 may be aligned with dies 114-2, 114-3. The dies 114-2, 114-3 may include a set of conductive contacts 122 on the bottom surface of the dies 114-2, 114-3. The conductive contacts 122 on the bottom surface of the dies 114-2, 114-3 may be aligned to electrically couple with the conductive contacts (e.g., first, second, third, and fourth conductive contacts 125, 126, 128, 129) at the second surface 170-2 of the substrate 107 (e.g., as shown in FIG. 1B). The conductive contacts 122 on the bottom surface of the dies 114-2, 114-3 may have a third thickness 193. In some embodiments, a third thickness 193 is between 2 microns and 35 microns. Although FIG. 1A shows the conductive contacts 122 on dies 114-2, 114-3 as having a same thickness 193, the conductive contacts 122 on the dies 114-2, 114-3 may have different thicknesses. The conductive contacts 122 on the bottom surface of the dies 114-2, 114-3 may further include solder 145.

As used herein, the terms “die,” “microelectronic component,” and similar variations may be used interchangeably. The die 114 may include other conductive pathways (e.g., including lines and vias) and/or to other circuitry (not shown) coupled to the respective conductive contacts (e.g., conductive contacts 122, 124) on the surface of the die 114. The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a Ill-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 8. The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked).

As shown in FIG. 1B, the N metal layer may include conductive contacts (e.g., conductive contacts 125, 126, 128, 129) at a top surface 170-2 of the substrate 107 that are coupled to conductive contacts 122 at bottom surfaces of the die 114-2, 114-3 by die-to-die (DTD) interconnects 130 and die-to-substrate (DTS) interconnects 140. The bridge die 114-1 may be electrically coupled to dies 114-2, 114-3 by DTD interconnects 130 (e.g., DTD interconnects 130-1, 130-2) at a second surface 170-2. In particular, conductive contacts 124 on a top surface of the die 114-1 may be coupled to conductive contacts 122 on a bottom surface of die 114-2 by DTD interconnects 130-1 and to conductive contacts 122 on a bottom surface of die 114-3 by DTD interconnects 130-2 by conductive pathways (e.g., conductive material 108) through the dielectric material 112. Conductive contacts 122 on a bottom surface of dies 114-2, 114-3 may be electrically coupled to conductive contacts 125, 129 at a second surface 170-2 of substrate 107 by DTS interconnects 140 (e.g., DTS interconnects 140-1, 140-2). In particular, conductive contacts 122 at a bottom surface of die 114-2 may be coupled by DTS interconnects 140-1 to conductive contacts 125 at a second surface 170-2 of the substrate 107 and conductive contacts 122 at a bottom surface of die 114-3 may be coupled by DTS interconnects 140-2 to conductive contacts 129 at the second surface 170-2 of the substrate 107. The DTD interconnects 130 and the DTS interconnects 140 may include solder 145 with nickel or tin, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. Some solder interconnects may form intermetallic compounds (IMCs) when current flows, in such embodiments, DTD interconnects 130 and DTS interconnects 140 may further include an IMC (not shown). In some embodiments, the DTD interconnects 130-1 and the DTS interconnects 140-1 may include solder 145 having a thickness 195 between 2 microns and 35 microns. In some embodiments, the DTD interconnects 130-2 and the DTS interconnects 140-2 may include solder 145 having a thickness 197 between 5 microns and 50 microns.

As shown in FIG. 1B, the substrate 107 may be coupled to a package substrate 102 by substrate-to-package-substrate (STPS) interconnects 150. In particular, the top surface of the package substrate 102 may include a set of conductive contacts 146. Conductive contacts 144 on the bottom surface of the substrate 107 may be electrically and mechanically coupled to the conductive contacts 146 on the top surface of the package substrate 102 by the STPS interconnects 150. The package substrate 102 may include an insulating material (e.g., a dielectric material formed in multiple layers, as known in the art) and one or more conductive pathways to route power, ground, and signals through the dielectric material (e.g., including conductive traces and/or conductive vias, as shown). In some embodiments, the insulating material of the package substrate 102 may be a dielectric material, such as an organic dielectric material, a fire retardant grade 4 material (FR-4), BT resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the package substrate 102 is formed using standard printed circuit board (PCB) processes, the package substrate 102 may include FR-4, and the conductive pathways in the package substrate 102 may be formed by patterned sheets of copper separated by build-up layers of the FR-4. The conductive pathways in the package substrate 102 may be bordered by liner materials, such as adhesion liners and/or barrier liners, as suitable. In some embodiments, the package substrate 102 may be formed using a lithographically defined via packaging process. In some embodiments, the package substrate 102 may be manufactured using standard organic package manufacturing processes, and thus the package substrate 102 may take the form of an organic package. In some embodiments, the package substrate 102 may be a set of redistribution layers formed on a panel carrier by laminating or spinning on a dielectric material, and creating conductive vias and lines by laser drilling and plating. In some embodiments, the package substrate 102 may be formed on a removable carrier using any suitable technique, such as a redistribution layer technique. Any method known in the art for fabrication of the package substrate 102 may be used, and for the sake of brevity, such methods will not be discussed in further detail herein.

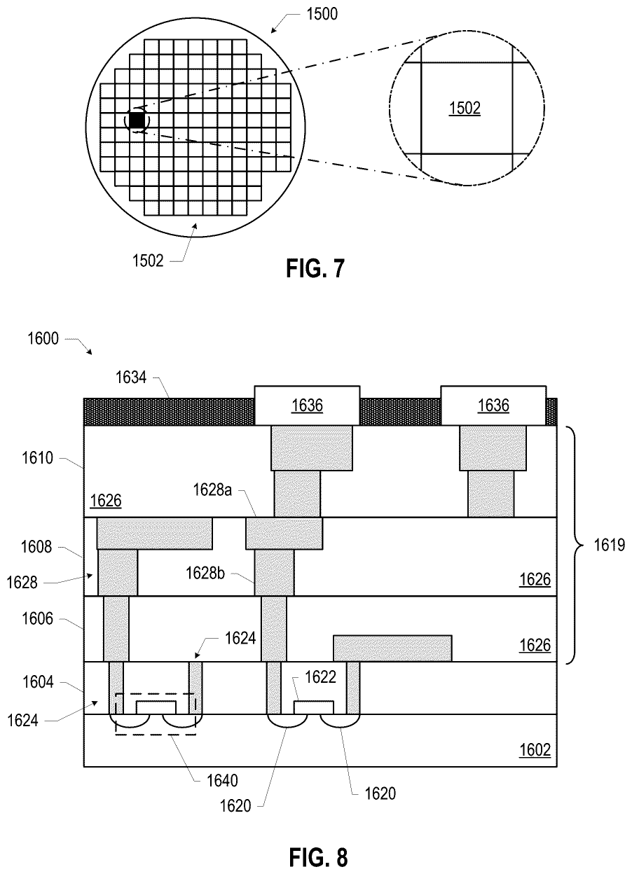

In some embodiments, the die 114 may include conductive pathways to route power, ground, and/or signals to/from other dies 114 included in the microelectronic assembly 100. For example, the die 114-1 may include TSVs, including a conductive material via, such as a metal via, isolated from the surrounding silicon or other semiconductor material by a barrier oxide), or other conductive pathways through which power, ground, and/or signals may be transmitted between the package substrate 102 and one or more dies 114 “on top” of the die 114-1 (e.g., in the embodiment of FIGS. 1A and 1B, the dies 114-2 and/or 114-3). In some embodiments, the die 114-1 may not route power and/or ground to the dies 114-2 and 114-3; instead, the dies 114-2, 114-3 may couple directly to power and/or ground lines in the package substrate 102 by STPS interconnects 150, conductive pathways 108 in the substrate 107, and DTS interconnects 140. In some embodiments, the die 114-1 may be thicker than the dies 114-2, 114-3. In some embodiments, the die 114-1 may be a memory device (e.g., as described below with reference to the die 1502 of FIG. 7), or a high frequency serializer and deserializer (SerDes), such as a Peripheral Component Interconnect (PCI) express. In some embodiments, the die 114-1 may be a processing die, a radio frequency chip, a power converter, a network processor, a workload accelerator, a voltage regulator die, or a security encryptor. In some embodiments, the die 114-2 and/or the die 114-3 may be a processing die, a radio frequency chip, a power converter, a network processor, a workload accelerator, a voltage regulator die, or a security encryptor.

In some embodiments, the package substrate 102 may be a lower density medium and the die 114 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual damascene process. In some embodiments, additional dies may be disposed on the top surface of the dies 114-2, 114-3. In some embodiments, additional components may be disposed on the top surface of the dies 114-2, 114-3. Additional passive components, such as surface-mount resistors, capacitors, and/or inductors, may be disposed on the top surface or the bottom surface of the package substrate 102, or embedded in the package substrate 102.

The microelectronic assembly 100 of FIG. 1B may also include an underfill material 127. In some embodiments, the underfill material 127 may extend between the substrate 107 and the package substrate 102 around the associated STPS interconnects 150. In some embodiments, the underfill material 127 may extend between different ones of the top level dies 114-2, 114-3 and the top surface of the substrate 107 (not shown) around the associated DTS interconnects 140 and between the bridge die 114-1 and the top level dies 114-2, 114-3 around the DTD interconnects 130. The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering the multi-layer die subassembly 104 to the package substrate 102 when forming the STPS interconnects 150, and then polymerizes and encapsulates the STPS interconnects 150. The underfill material 127 may be selected to have a coefficient of thermal expansion (CTE) that may mitigate or minimize the stress between the substrate 107 and the package substrate 102 arising from uneven thermal expansion in the microelectronic assembly 100. In some embodiments, the CTE of the underfill material 127 may have a value that is intermediate to the CTE of the package substrate 102 (e.g., the CTE of the dielectric material of the package substrate 102) and a CTE of the dies 114 and/or dielectric material 112 of the substrate 107.

The STPS interconnects 150 disclosed herein may take any suitable form. In some embodiments, a set of STPS interconnects 150 may include solder (e.g., solder bumps or balls that are subject to a thermal reflow to form the STPS interconnects 150), for example, as shown in FIG. 1, the STPS interconnects 150 may include solder between a conductive contacts 144 on a bottom surface of the substrate 107 and a conductive contact 146 on a top surface of the package substrate 102. In some embodiments, a set of STPS interconnects 150 may include an anisotropic conductive material, such as an anisotropic conductive film or an anisotropic conductive paste. An anisotropic conductive material may include conductive materials dispersed in a non-conductive material.

The DTD interconnects 130 disclosed herein may take any suitable form. The DTD interconnects 130 may have a finer pitch than the STPS interconnects 150 in a microelectronic assembly. In some embodiments, the dies 114 on either side of a set of DTD interconnects 130 may be unpackaged dies, and/or the DTD interconnects 130 may include small conductive bumps (e.g., copper bumps). The DTD interconnects 130 may have too fine a pitch to couple to the package substrate 102 directly (e.g., too fine to serve as DTS interconnects 140 or STPS interconnects 150). In some embodiments, a set of DTD interconnects 130 may include solder. In some embodiments, a set of DTD interconnects 130 may include an anisotropic conductive material, such as any of the materials discussed above. In some embodiments, the DTD interconnects 130 may be used as data transfer lanes, while the STPS interconnects 150 may be used for power and ground lines, among others. In some embodiments, some of the interconnects disclosed herein in a microelectronic assembly 100 may be metal-to-metal interconnects (e.g., copper-to-copper interconnects, or plated interconnects). In such embodiments, the interconnects may be bonded together (e.g., under elevated pressure and/or temperature) without the use of intervening solder or an anisotropic conductive material. Any of the conductive contacts disclosed herein (e.g., the conductive contacts 122, 124, 144, and/or 146) may include bond pads, solder bumps, conductive posts, or any other suitable conductive contact, for example. In some embodiments, some or all of the DTD interconnects 130 and/or the DTS interconnects 140 in a microelectronic assembly 100 may be solder interconnects that include a solder with a higher melting point than a solder included in some or all of the STPS interconnects 150. For example, when the DTD interconnects 130 and the DTS interconnects 140 in a microelectronic assembly 100 are formed before the STPS interconnects 150 are formed, solder-based DTD interconnects 130 and DTS interconnects 140 may use a higher-temperature solder (e.g., with a melting point above 200 degrees Celsius), while the STPS interconnects 150 may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

In the microelectronic assemblies 100 disclosed herein, some or all of the DTS interconnects 140 and the STPS interconnects 150 may have a larger pitch than some or all of the DTD interconnects 130. DTD interconnects 130 may have a smaller pitch than STPS interconnects 150 due to the greater similarity of materials in the different dies 114 on either side of a set of DTD interconnects 130 than between the substrate 107 and the top level dies 114-2, 114-3 on either side of a set of DTS interconnects 140, and between the substrate 107 and the package substrate 102 on either side of a set of STPS interconnects 150. In particular, the differences in the material composition of a substrate 107 and a die 114 or a package substrate 102 may result in differential expansion and contraction due to heat generated during operation (as well as the heat applied during various manufacturing operations). To mitigate damage caused by this differential expansion and contraction (e.g., cracking, solder bridging, etc.), the DTS interconnects 140 and the STPS interconnects 150 may be formed larger and farther apart than DTD interconnects 130, which may experience less thermal stress due to the greater material similarity of the pair of dies 114 on either side of the DTD interconnects. In some embodiments, the DTS interconnects 140 disclosed herein may have a pitch between 10 microns and 250 microns. In some embodiments, the STPS interconnects 150 disclosed herein may have a pitch between 55 microns and 3000 microns, while the DTD interconnects 130 disclosed herein may have a pitch between 5 microns and 120 microns.

The microelectronic assembly 100 of FIG. 1B may also include a circuit board (not shown). The package substrate 102 may be coupled to the circuit board by second-level interconnects at the bottom surface of the package substrate 102. The second-level interconnects may be any suitable second-level interconnects, including solder balls for a ball grid array arrangement, pins in a pin grid array arrangement or lands in a land grid array arrangement. The circuit board may be a motherboard, for example, and may have other components attached to it. The circuit board may include conductive pathways and other conductive contacts for routing power, ground, and signals through the circuit board, as known in the art. In some embodiments, the second-level interconnects may not couple the package substrate 102 to a circuit board, but may instead couple the package substrate 102 to another IC package, an interposer, or any other suitable component. In some embodiments, the substrate 107 may not be coupled to a package substrate 102, but may instead be coupled to a circuit board, such as a PCB.

Although FIG. 1 depicts a microelectronic assembly 100 having a substrate with a particular number of dies 114 and conductive pathways 108 coupled to other dies 114, this number and arrangement are simply illustrative, and a microelectronic assembly 100 may include any desired number and arrangement of dies 114. Although FIG. 1 shows the dies 114 as single-sided dies, the dies 114 may be double-sided dies and the dies 114 may be a single-pitch die (as shown for die 114-1) or a mixed-pitch die (as shown for dies 114-2, 114-3). In some embodiments, additional components may be disposed on the top surface of the dies 114-2 and/or 114-3. In this context, a double-sided die refers to a die that has connections on both surfaces. In some embodiments, a double-sided die may include through TSVs to form connections on both surfaces. The active surface of a double-sided die, which is the surface containing one or more active devices and a majority of interconnects, may face either direction depending on the design and electrical requirements.

Many of the elements of the microelectronic assembly 100 of FIG. 1 are included in other ones of the accompanying drawings; the discussion of these elements is not repeated when discussing these drawings, and any of these elements may take any of the forms disclosed herein. Further, a number of elements are illustrated in FIG. 1 as included in the microelectronic assembly 100, but a number of these elements may not be present in a microelectronic assembly 100. For example, in various embodiments, the core, 109, the further layers 111, the underfill material 127, and the package substrate 102 may not be included. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

FIG. 2A is a side, cross-sectional view of an example microelectronic assembly, in accordance with various embodiments. The configuration of the embodiment shown in FIG. 2A is like that of FIG. 1A, except for differences as described further. The microelectronic assembly 100 in FIG. 2A may include a multi-layer die subassembly 104. As used herein, the term a “multi-layer die subassembly” 104 may refer to a composite die having two or more stacked dielectric layers with one or more dies in each layer, and conductive interconnects and/or conductive pathways connecting the one or more dies, including dies in non-adjacent layers. As used herein, the terms a “multi-layer die subassembly” and a “composite die” may be used interchangeably. As shown in FIGS. 2A and 2B, the multi-layer die subassembly 104 may include two or more layers. In particular, the multi-layer die subassembly 104 may include a first layer 104-1 having a die 114-1 and a conductive pillar 152 and a second layer 104-2 having a die 114-2 and a die 114-3. The first layer 104-1 may include a first surface 170-1 and an opposing second surface 170-2. The second surface 170-2 of the first layer 104-1 of the multi-layer die subassembly 104 may include first and second conductive contacts 125, 126 having a first thickness 191 and a first material 118 on a top surface, and third and fourth conductive contacts 128, 129 having a second thickness 192 and a second material 116 and solder 145 at a top surface, as described above with reference to FIG. 1A. The die 114-1 may function as a bridge component between dies 114-2, 114-3. The die 114-1 may be referred to herein as “a first level die,” “a bottom die,” or “an embedded die.” The dies 114-2, 114-3 may be referred to herein as “second level dies” or “top dies.” The dies 114-2, 114-3 in the second layer 104-2 may be coupled to the package substrate 102 by conductive pathways (e.g., conductive material 108) and conductive pillars 152 to form multi-level (ML) interconnects. The ML interconnects may be power delivery interconnects or high speed signal interconnects. As used herein, the term “ML interconnect” may refer to an interconnect that includes a conductive pillar between a first component and a second component where the first component and the second component are not in adjacent layers, or may refer to an interconnect that spans one or more layers (e.g., an interconnect between a first die in a first layer and a second die in a third layer, or an interconnect between a package substrate and a die in a second layer).

As shown in FIG. 2B, the top surface metal layer (e.g., the second surface 170-2) of the first layer 104-1 may include conductive contacts (e.g., conductive contacts 125, 126, 128, 129) that are coupled to conductive contacts 122 at bottom surfaces of the die 114-2, 114-3 by DTD interconnects 130-1, 130-2 and DTS interconnects 140-1, 140-2, as described above with reference to FIG. 1B.

As shown in FIG. 2B, conductive contacts 122 on the bottom surface of the dies 114-2, 114-3 may be electrically and mechanically coupled to conductive pillars 152 by DTS interconnects 140 (e.g., DTS interconnects 140-1, 140-2) and conductive pillars 152 may be electrically coupled to the package substrate 102 by STPS interconnects 150. The conductive pillars 152 may be formed of any suitable conductive material, such as copper, silver, nickel, gold, aluminum, or other metals or alloys, for example. The conductive pillars 152 may be formed using any suitable process, including, for example, a lithographic process or an additive process, such as cold spray or 3-dimensional printing. In some embodiments, the conductive pillars 152 disclosed herein may have a pitch between 55 microns and 1000 microns. As used herein, pitch is measured center-to-center (e.g., from a center of a conductive pillar to a center of an adjacent conductive pillar). The conductive pillars 152 may have any suitable size and shape. In some embodiments, the conductive pillars 152 may have a circular, rectangular, or other shaped cross-section.

The multi-layer die subassembly 104 may include an insulating material 132 (e.g., a dielectric material formed in multiple layers, as known in the art) to form the multiple layers and to embed one or more dies in a layer. In particular, the first die 114-1 and conductive pillars 152 may be surrounded by the insulating material 132 in the first layer 104-1 and, as shown in FIG. 2B, the second and third dies 114-2, 114-3 may be surrounded by the insulating material 132 in the second layer 104-2. In some embodiments, the insulating material 132 of the multi-layer die subassembly 104 may be a dielectric material, such as an organic dielectric material, a fire retardant grade 4 material (FR-4), bismaleimide triazine (BT) resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics). In some embodiments, the die 114 may be embedded in an inhomogeneous dielectric, such as stacked dielectric layers (e.g., alternating layers of different inorganic dielectrics). In some embodiments, the insulating material 132 of the multi-layer die subassembly 104 may be a mold material, such as an organic polymer with inorganic silica particles. The multi-layer die subassembly 104 may include one or more ML interconnects through the dielectric material (e.g., including conductive vias and/or conductive pillars, as shown). The multi-layer die subassembly 104 may further include conductive material 108 (e.g., conductive pathways including conductive lines and vias) through the insulating material 132 that couple the dies 114-2, 114-3 to the conductive pillars 152 and the die 114-1, as shown in FIG. 2B.

The multi-layer die subassembly 104 may have any suitable dimensions. For example, in some embodiments, a thickness of the multi-layer die subassembly 104 may be between 100 um and 2000 um. In some embodiments, the multi-layer die subassembly 104 may include a composite die, such as stacked dies. The multi-layer die subassembly 104 may have any suitable number of layers, any suitable number of dies, and any suitable die arrangement. For example, in some embodiments, the multi-layer die subassembly 104 may have between 3 and 20 layers of dies. In some embodiments, the multi-layer die subassembly 104 may include a layer having between 2 and 50 dies.

In some embodiments, the multi-layer die subassembly 104 may further include a redistribution layer (RDL) (not shown) at a bottom surface 170-2 and/or between the first and second layers 104-1, 104-2. An RDL may include an insulating material (e.g., a dielectric material formed in multiple layers, as known in the art) and one or more conductive pathways through the dielectric material (e.g., including conductive traces and/or conductive vias). In some embodiments, the insulating material of the RDL may be composed of dielectric materials, bismaleimide triazine (BT) resin, polyimide materials, epoxy materials (e.g., glass reinforced epoxy matrix materials, epoxy build-up films, or the like), mold materials, oxide-based materials (e.g., silicon dioxide or spin on oxide), or low-k and ultra low-k dielectric (e.g., carbon-doped dielectrics, fluorine-doped dielectrics, porous dielectrics, and organic polymeric dielectrics).

Although FIG. 2 depicts a microelectronic assembly 100 having a multi-layer die subassembly 104 with a particular number of dies 114 coupled to the package substrate 102 and to other dies 114, this number and arrangement are simply illustrative, and a multi-layer die subassembly 104 may include any desired number and arrangement of dies 114 coupled to a package substrate 102. Although FIG. 2 shows the die 114 as single-sided die, the dies 114 may be a single-sided or a double-sided die and may be a single-pitch die or a mixed-pitch die. In some embodiments, additional components may be disposed on the top surface of the dies 114-2 and/or 114-3. In this context, a double-sided die refers to a die that has connections on both surfaces. In some embodiments, a double-sided die may include through TSVs to form connections on both surfaces. The active surface of a double-sided die, which is the surface containing one or more active devices and a majority of interconnects, may face either direction depending on the design and electrical requirements. A number of elements are illustrated in FIG. 2 as included in the microelectronic assembly 100, but a number of these elements may not be present in a microelectronic assembly 100. For example, in various embodiments, the underfill material 127, the surface insulation material 117, and the package substrate 102 may not be included.

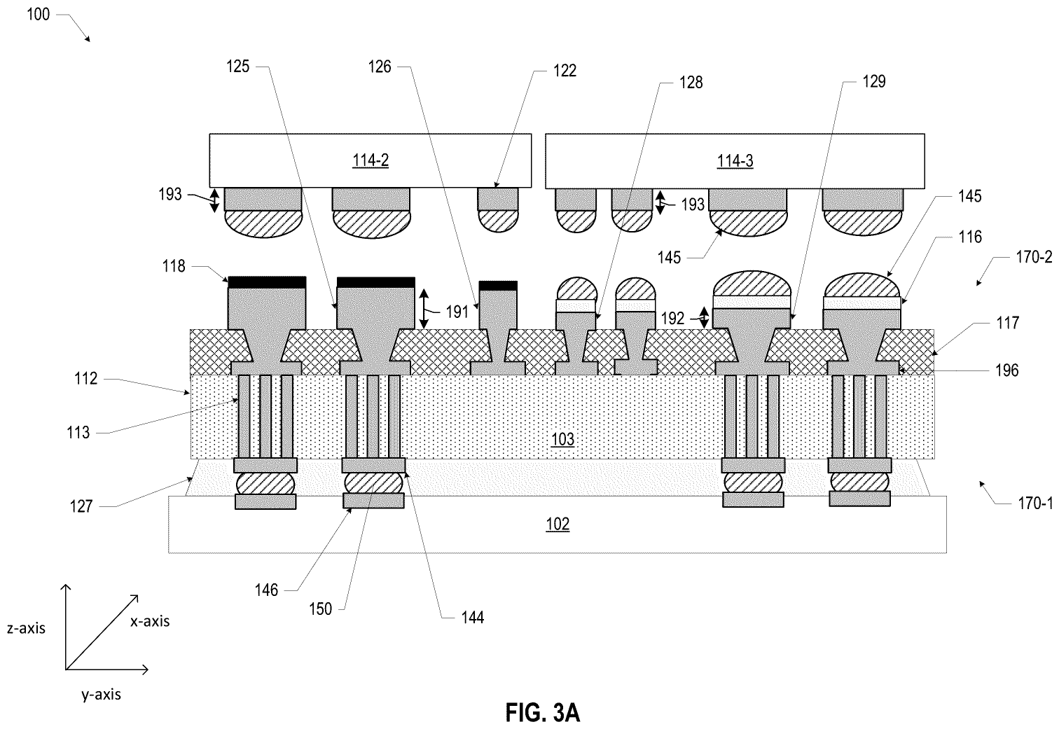

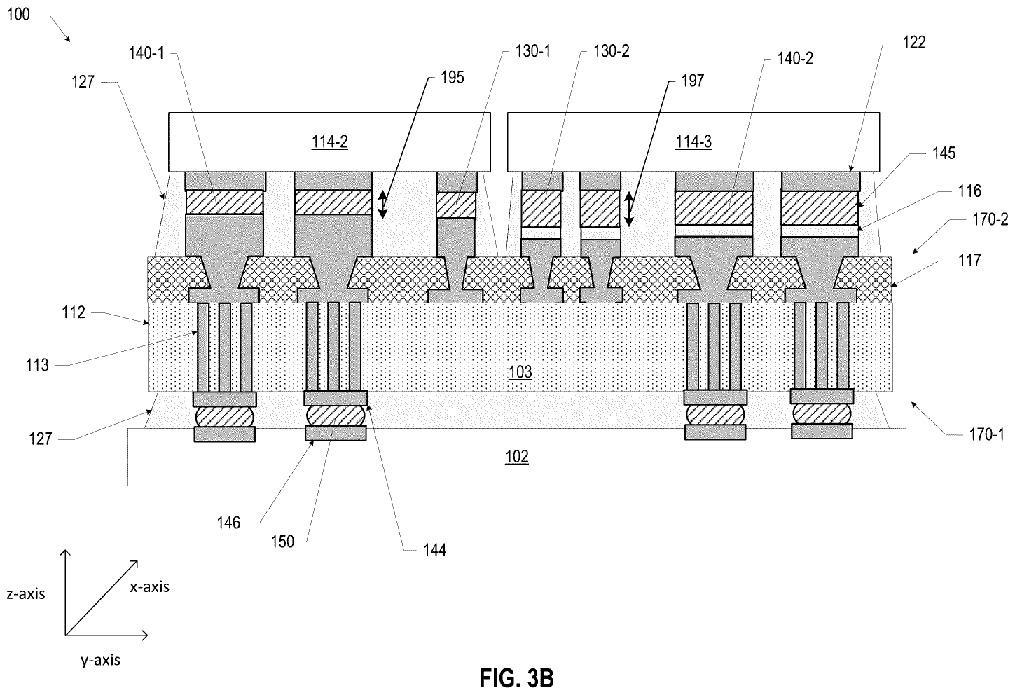

FIG. 3A is a side, cross-sectional view of an example microelectronic assembly, in accordance with various embodiments. The configuration of the embodiment shown in FIG. 3A is like that of FIG. 2A, except for differences as described further. The microelectronic assembly 100 in FIG. 3A may include a base die 103 having a first surface 170-1 and an opposing second surface 170-2, where the second surface 170-2 includes first and second conductive contacts 125, 126 having a first thickness 191 and a first material 118 on a top surface, and third and fourth conductive contacts 128, 129 having a second thickness 192 and a second material 116 and solder 145 at a top surface, as described above with reference to FIG. 1A. The base die 103 may function as a bridge component between dies 114-2, 114-3. The base die 103 also may be referred to herein as “a bottom die” and the dies 114-2, 114-3 may be referred to herein as “top dies.” In some embodiments, a base die 103 may include an interposer. The dies 114-2, 114-3 may be coupled to the package substrate 102 by conductive pathways (e.g., conductive vias 113) through a dielectric material 112 (e.g., a dielectric material 112, as described above with reference to FIG. 1A) of the base die 103. The conductive vias 113 may be power delivery interconnects or high speed signal interconnects. The conductive vias 113 may include a metal, such as copper.

As shown in FIG. 3B, the top surface metal layer (e.g., the second surface 170-2) of the base die 103 may include conductive contacts (e.g., conductive contacts 125, 126, 128, 129) that are coupled to conductive contacts 122 at bottom surfaces of the die 114-2, 114-3 by DTD interconnects 130-1, 130-2 and DTS interconnects 140-1, 140-2, as described above with reference to FIG. 1B.

Although FIG. 3 depicts a microelectronic assembly 100 having a single base die 103 coupled to the package substrate 102 and to other dies 114, this number and arrangement are simply illustrative, and a microelectronic assembly 100 may include any desired number and arrangement of base dies 103 coupled to a package substrate 102 and any desired number and arrangement of dies 114 coupled to a base die 103. Although FIG. 3 shows the die 114 as single-sided die, the dies 114 may be a single-sided or a double-sided die and may be a single-pitch die or a mixed-pitch die. In some embodiments, additional components may be disposed on the top surface of the dies 114-2 and/or 114-3. In this context, a double-sided die refers to a die that has connections on both surfaces. In some embodiments, a double-sided die may include through TSVs to form connections on both surfaces. The active surface of a double-sided die, which is the surface containing one or more active devices and a majority of interconnects, may face either direction depending on the design and electrical requirements. A number of elements are illustrated in FIG. 3 as included in the microelectronic assembly 100, but a number of these elements may not be present in a microelectronic assembly 100. For example, in various embodiments, the underfill material 127, the surface insulation material 117, and the package substrate 102 may not be included.

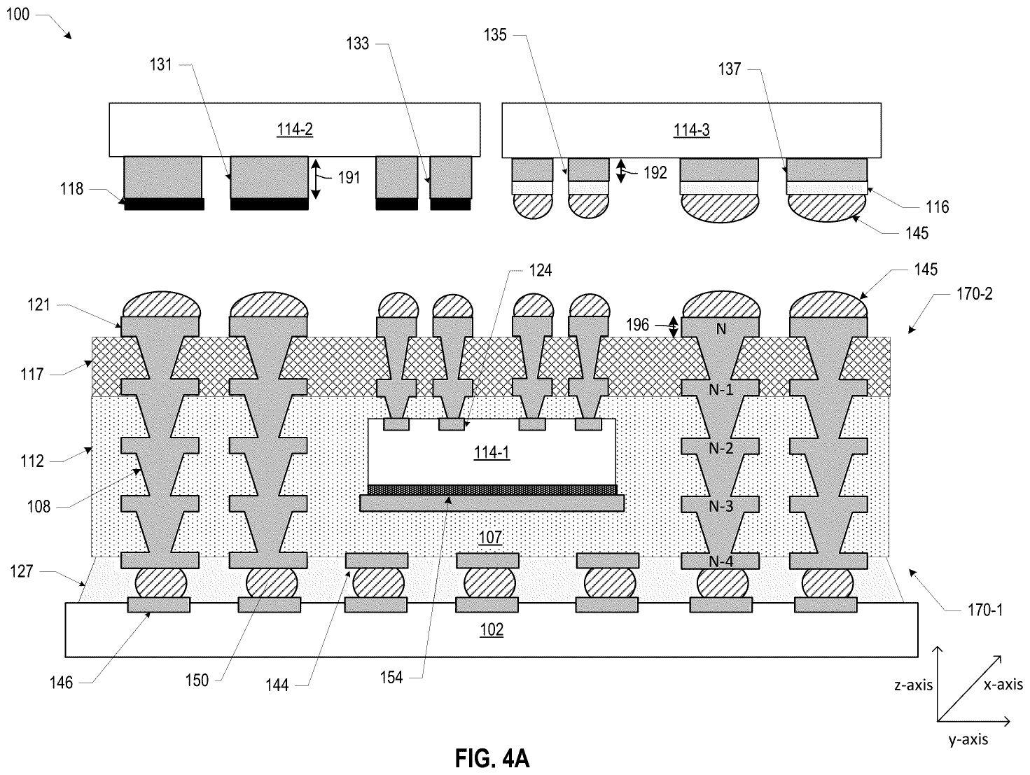

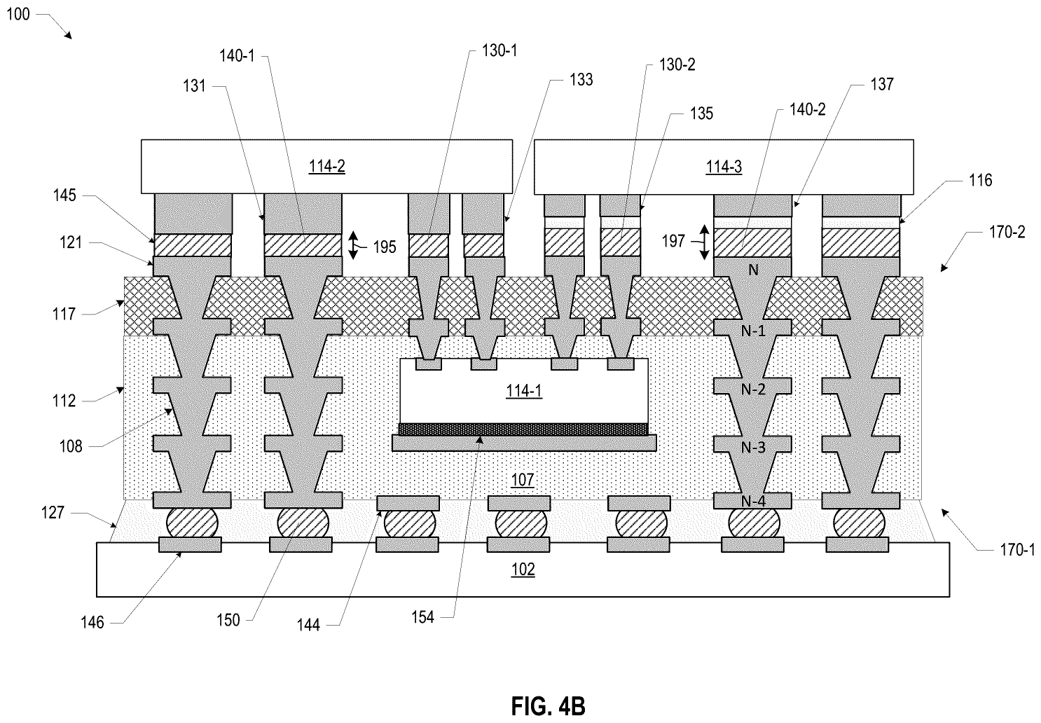

FIG. 4A is a side, cross-sectional view of an example microelectronic assembly, in accordance with various embodiments. The configuration of the embodiment shown in FIG. 4A is like that of FIG. 1A, except for differences as described further. The microelectronic assembly 100 may include a substrate 107 with a first surface 170-1 and an opposing second surface 170-2, the second surface 170-2 including conductive contacts 121 having a thickness 196. In some embodiments, a thickness 196 is between 3 microns and 50 microns. Although FIG. 4A shows the conductive contacts 121 as having a same thickness 193, the conductive contacts 121 may have different thicknesses. The conductive contacts 121 on the top surface 170-2 of the substrate 107 may further include solder 145. As shown in FIG. 4A, the substrate 107 may be aligned with dies 114-2, 114-3. The dies 114-2, 114-3 may include conductive contacts (e.g., conductive contacts 131, 133, 135, 137) on a bottom surface of the dies 114-2, 114-3 that may be aligned to electrically couple with the conductive contacts (e.g., conductive contacts 121) at the second surface 170-2 of the substrate 107 (e.g., as shown in FIG. 4B). In particular, the die 114-2 may include a first conductive contact 131 and a second conductive contact 133 having a first thickness 191 and the die 114-3 may include a third conductive contact 135 and a fourth conductive contact 137 having a second thickness 192 different than the first thickness 191. In some embodiments, a first thickness 191 is greater than a second thickness 192 and having dimensions as described above with reference to FIG. 1. In some embodiments, the first and second conductive contacts 131, 133 may include the first material 118 (e.g., a surface finish or a liner material) on a bottom surface, which may protect the underlying material of the conductive contact from corrosion, as described above with reference to FIG. 1. In some embodiments, the third and fourth conductive contacts 135, 137 may include solder 145 at a bottom surface of the third and fourth conductive contacts 135, 137, as described above with reference to FIG. 1. In some embodiments, the third and fourth conductive contacts 135, 137 may include the second material 116 between a bottom surface of the third and fourth conductive contacts 135, 137 and the solder 145, as described above with reference to FIG. 1.

As shown in FIG. 4B, the N metal layer may include conductive contacts 121 at a top surface 170-2 of the substrate 107 that are coupled to conductive contacts 131, 133, 135, 137 at bottom surfaces of the die 114-2, 114-3 by DTD interconnects 130 and DTS interconnects 140. The bridge die 114-1 may be electrically coupled to dies 114-2, 114-3 by DTD interconnects 130 (e.g., DTD interconnects 130-1, 130-2) at a second surface 170-2. In particular, conductive contacts 124 on a top surface of the die 114-1 may be coupled to conductive contacts 133 on a bottom surface of die 114-2 by DTD interconnects 130-1 and to conductive contacts 135 on a bottom surface of die 114-3 by DTD interconnects 130-2 and by conductive pathways (e.g., conductive material 108) through the dielectric material 112. Conductive contacts 131, 137 on a bottom surface of die 114-2, 114-3 may be electrically coupled to conductive contacts 121 at a second surface 170-2 of substrate 107 by DTS interconnects 140. In particular, conductive contacts 131 at a bottom surface of die 114-2 may be coupled by DTS interconnects 140-1 to conductive contacts 121 at a second surface 170-2 of the substrate 107 and conductive contacts 137 at a bottom surface of die 114-3 may be coupled by DTS interconnects 140-2 to conductive contacts 121 at the second surface 170-2 of the substrate 107. The DTD interconnects 130 and the DTS interconnects 140 may include solder 145. In some embodiments, the DTD interconnects 130-1 and the DTS interconnects 140-1 may include solder 145 having a thickness 195 and the DTD interconnects 130-2 and the DTS interconnects 140-2 may include solder 145 having a thickness 197, as described above with reference to FIG. 1.

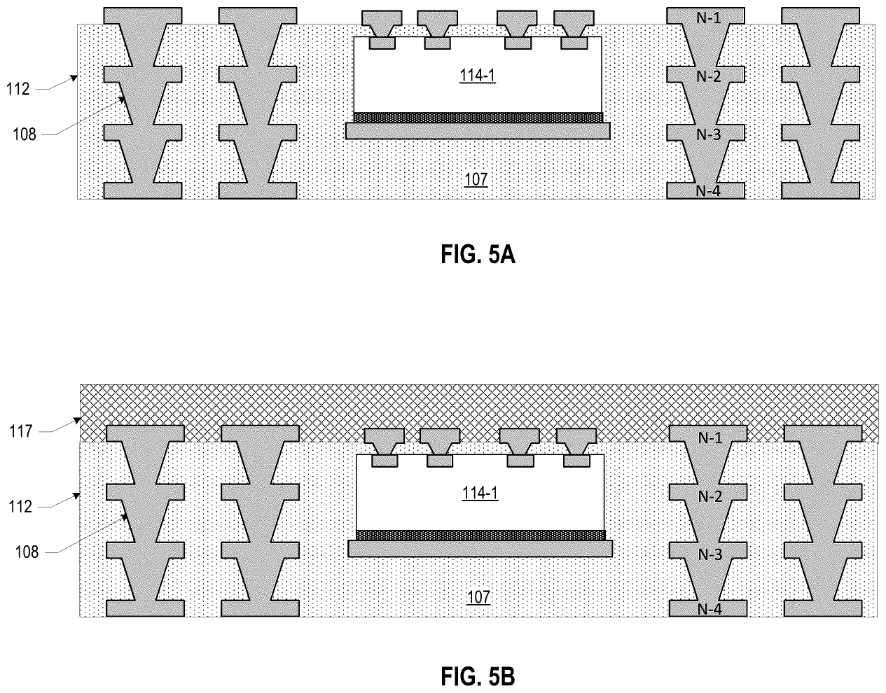

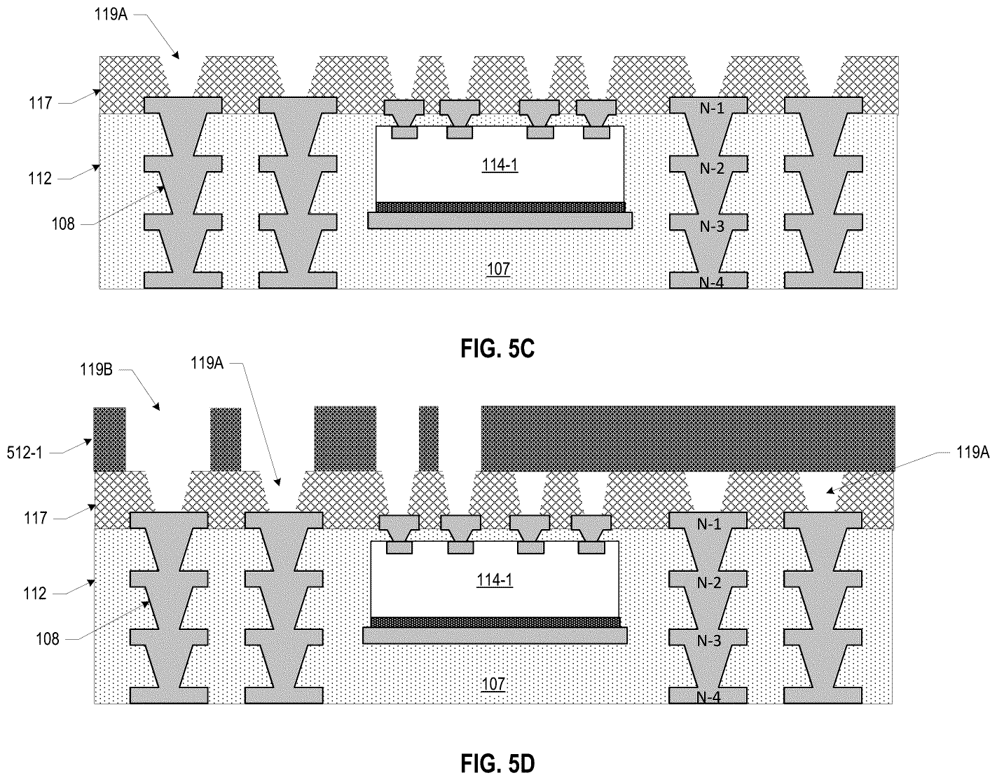

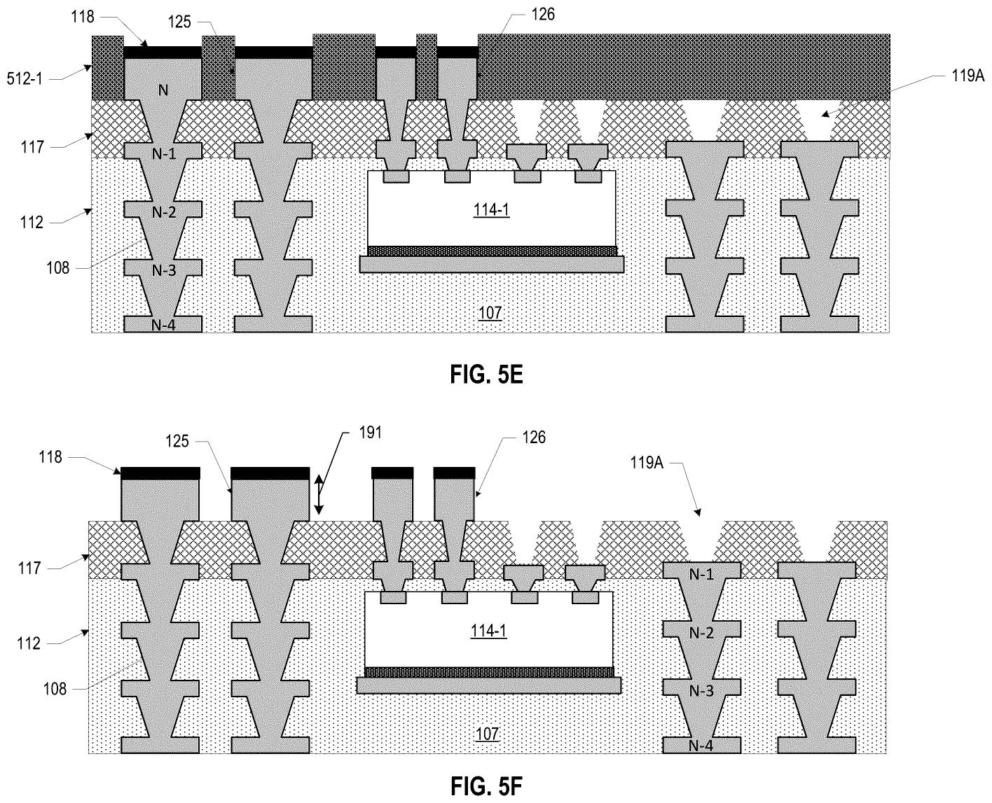

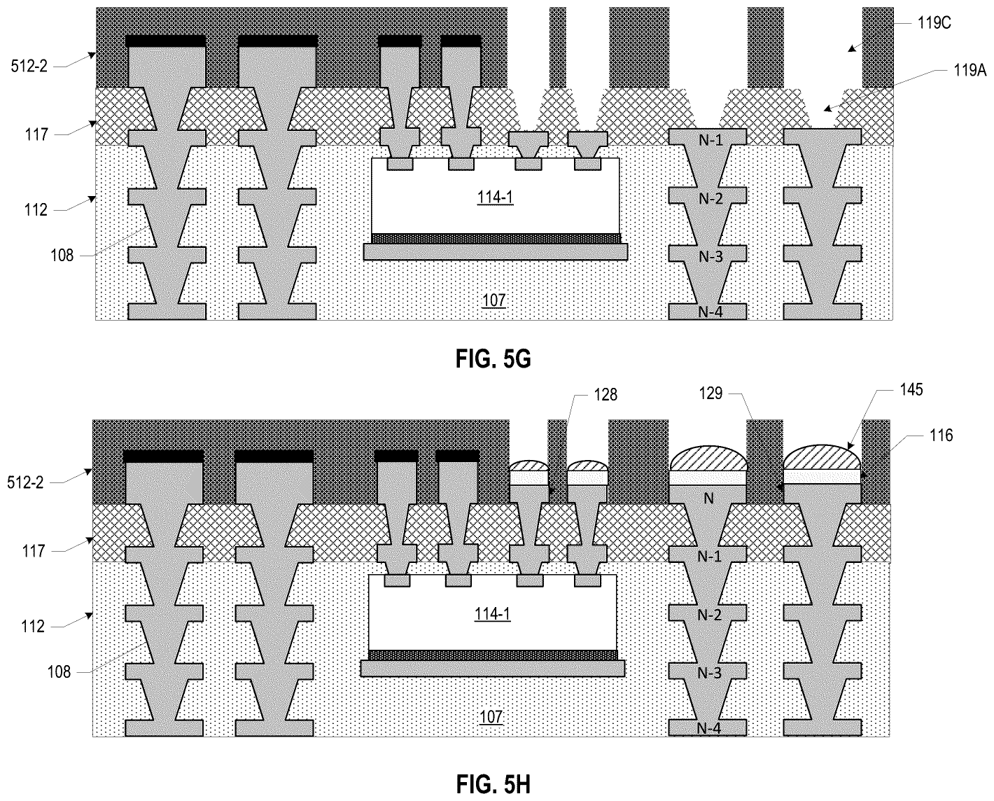

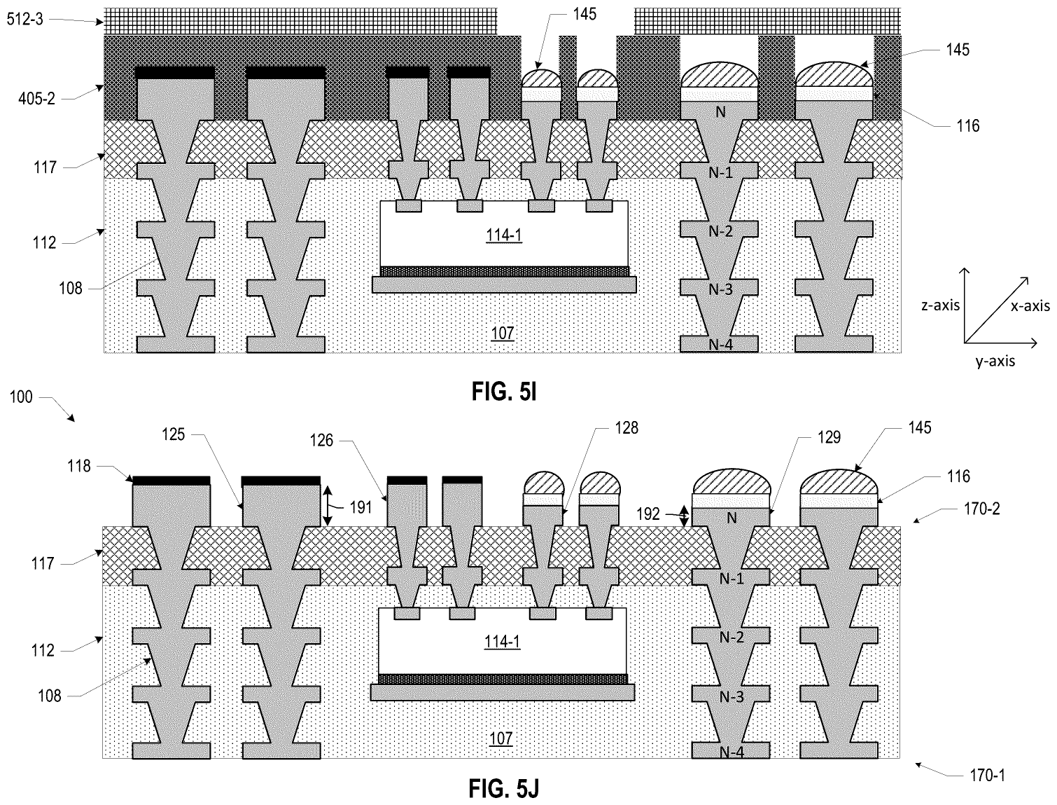

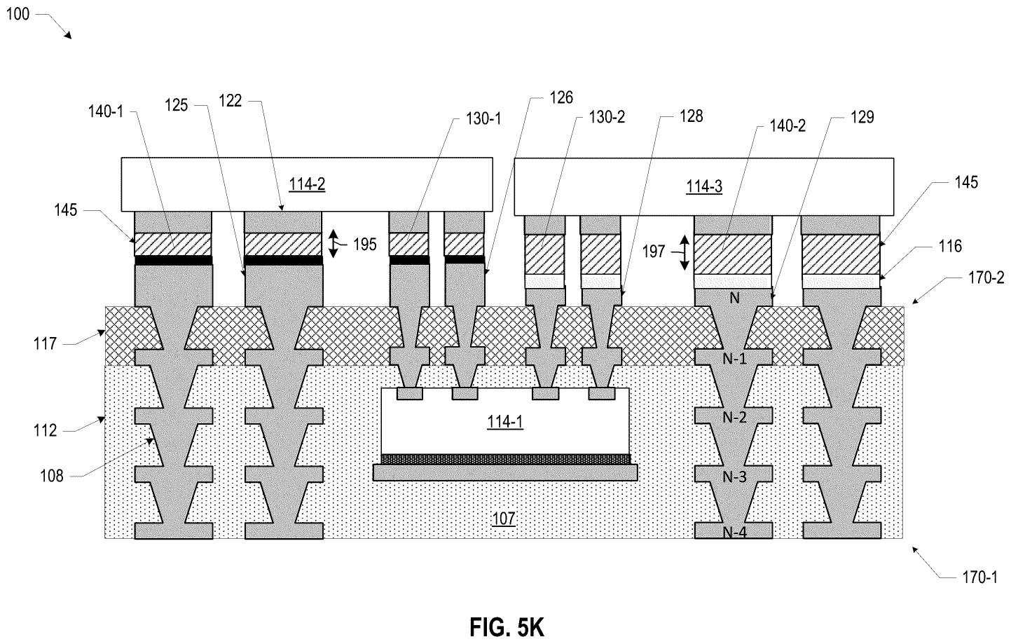

Any suitable techniques may be used to manufacture the microelectronic assemblies 100 disclosed herein. For example, FIGS. 5A-5K are side, cross-sectional views of various stages in an example process for manufacturing the microelectronic assembly 100 similar to FIG. 1A, in accordance with various embodiments. Although the operations discussed below with reference to FIGS. 5A-5K are illustrated in a particular order, these operations may be performed in any suitable order. Further, additional operations which are not illustrated may also be performed without departing from the scope of the present disclosure. Also, various ones of the operations discussed herein with respect to FIGS. 5A-5K may be modified in accordance with the present disclosure to fabricate others of microelectronic assembly 100 disclosed herein.

FIG. 5A illustrates an assembly subsequent to forming a substrate 107 with a top surface including patterned conductive contacts (e.g., conductive features of N−1 metal layer). The assembly of FIG. 5A may be manufactured using conventional package substrate manufacturing techniques (e.g., lamination of layers of the dielectric material 112, etc.), and may include layers up to N−1. In other embodiments, the assembly of FIG. 5A may include a multi-layer die subassembly 104 (e.g., as shown in FIG. 2), a base 103 (e.g., as shown in FIG. 3), or a die 114-2, 114-3 (e.g., as shown in FIG. 4) having a top surface including patterned conductive contacts.

FIG. 5B illustrates an assembly subsequent to forming a layer of surface insulation material 117 on a top surface of the assembly of FIG. 5A.

FIG. 5C illustrates an assembly subsequent to patterning openings 119A in the surface insulation material 117 of the assembly of FIG. 5B to expose the underlying metal of the conductive contacts. In some embodiments, the openings 119A in the surface insulation material 117 may be formed by mechanical patterning, laser patterning, dry etch patterning, or lithographic patterning techniques. In some embodiments, a conductive seed layer (not shown) may be deposited in the openings 119A and on the top surface of the surface insulation material 117. The conductive seed layer may include a metal, such as copper.

FIG. 5D illustrates an assembly subsequent to applying a first photoresist 512-1 to a top surface of the assembly of FIG. 5C and lithographically patterning the first photoresist 512-1 to form openings 119B. In some embodiments, before patterning, the surface insulation material 117 may be planarized by grinding, lapping or chemical mechanical polishing to reduce surface roughness and comply with flatness requirements for photolithography. The first photoresist 512-1 may be a liquid or dry film type.

FIG. 5E illustrates an assembly subsequent to depositing a conductive material, such as copper, in the openings 119A and 119B to form a first portion of the N metal layer (e.g., conductive contacts 125, 126), and depositing a first material 118 on a top surface of the N metal layer. The first portion of the N metal layer and the first material 118 may be deposited using any suitable technique, such as electroless plating or electrolytic plating.

FIG. 5F illustrates an assembly subsequent to removing the first photoresist layer 512-1 from the assembly of FIG. 5E. The first portion of the N metal layer may include conductive contacts 125, 126 with a thickness 191.

FIG. 5G illustrates an assembly subsequent to applying a second photoresist 512-2 to a top surface of the assembly of FIG. 5F and lithographically patterning the second photoresist 512-2 to form openings 119C. The second photoresist 512-2 may be a liquid or dry film type.

FIG. 5H illustrates an assembly subsequent to depositing a conductive material, such as copper, in the openings 119 A and 119C to form a second portion of the N metal layer (e.g., conductive contacts 128, 129), depositing a second material 116 on a top surface of the N metal layer, and depositing solder 145 on a top surface of the second material 116. The second portion of the N metal layer, the second material 116, and the solder 145 may be deposited using any suitable technique, such as electroless plating or electrolytic plating.

FIG. 5I illustrates an assembly subsequent to applying a third photoresist 512-3 to a top surface of the assembly of FIG. 5H, lithographically patterning the third photoresist 512-3 to form openings 119D, and depositing additional solder 145 in the openings 119D to increase a thickness (e.g., a z-height) of the solder 145 at a top surface of conductive contacts 128. The third photoresist 512-3 may be a liquid or dry film type. The additional solder 145 may be deposited using any suitable technique, such as electroless plating or electrolytic plating.

FIG. 5J illustrates an assembly subsequent to removing the second and third photoresist layers 512-2, 512-3 from the assembly of FIG. 5I. If multiple assemblies are manufactured together, the assemblies may be singulated. The assembly of FIG. 5J may itself be a microelectronic assembly 100, as shown. Further manufacturing operations may be performed on the microelectronic assembly 100 of FIG. 5J to form other microelectronic assembly 100; for example, performing finishing operations on the bottom surface of the assembly, such as depositing solder resist, depositing solder on a bottom surface (e.g., at the first surface 170-1) of conductive contacts of N−4 metal layer, and coupling the microelectronic assembly 100 of FIG. 5J to a package substrate 102 via STPS interconnects 150, similar to the microelectronic assembly 100 of FIG. 1A.

FIG. 5K illustrates an assembly subsequent to placing dies 114-2, 114-3 on a top surface of the assembly of FIG. 5J and forming DTD interconnects 130-1, 130-2 and DTS interconnects 140-1, 140-2. Any suitable method may be used to place the dies 114-2, 114-3, for example, automated pick-and-place. The dies 114-2, 114-3 may include a set of first conductive contacts 122. In some embodiments, the DTD interconnects 130 and DTS interconnects 140 may include solder. In such embodiments, the assembly of FIG. 5K may be subjected to a solder reflow process during which solder components of the DTD interconnects 130 and DTS interconnects 140 melt and bond to mechanically and electrically couple the dies 114-2, 114-3 to the top surface of the assembly of FIG. 5J. In some embodiments, the DTD interconnects 130-1 and the DTS interconnects 140-1 may include solder 145 having a thickness 195, and the DTD interconnects 130-2 and the DTS interconnects 140-2 may include solder 145 having a thickness 197. In some embodiments, underfill 127 may be dispensed around the DTD interconnects 130 and DTS interconnects 140. In some embodiments, underfill 127 around the DTD interconnects 130 and DTS interconnects 140 may be omitted. If multiple assemblies are manufactured together, the assemblies may be singulated. The assembly of FIG. 5K may itself be a microelectronic assembly 100, as shown. Further manufacturing operations may be performed on the microelectronic assembly 100 of FIG. 5K to form other microelectronic assembly 100; for example, performing finishing operations on the bottom surface of the assembly, such as depositing solder resist, depositing solder on a bottom surface (e.g., at the first surface 170-1) of conductive contacts of N−4 metal layer, and coupling the microelectronic assembly 100 of FIG. 5K to a package substrate 102 via STPS interconnects 150, similar to the microelectronic assembly 100 of FIG. 1A.

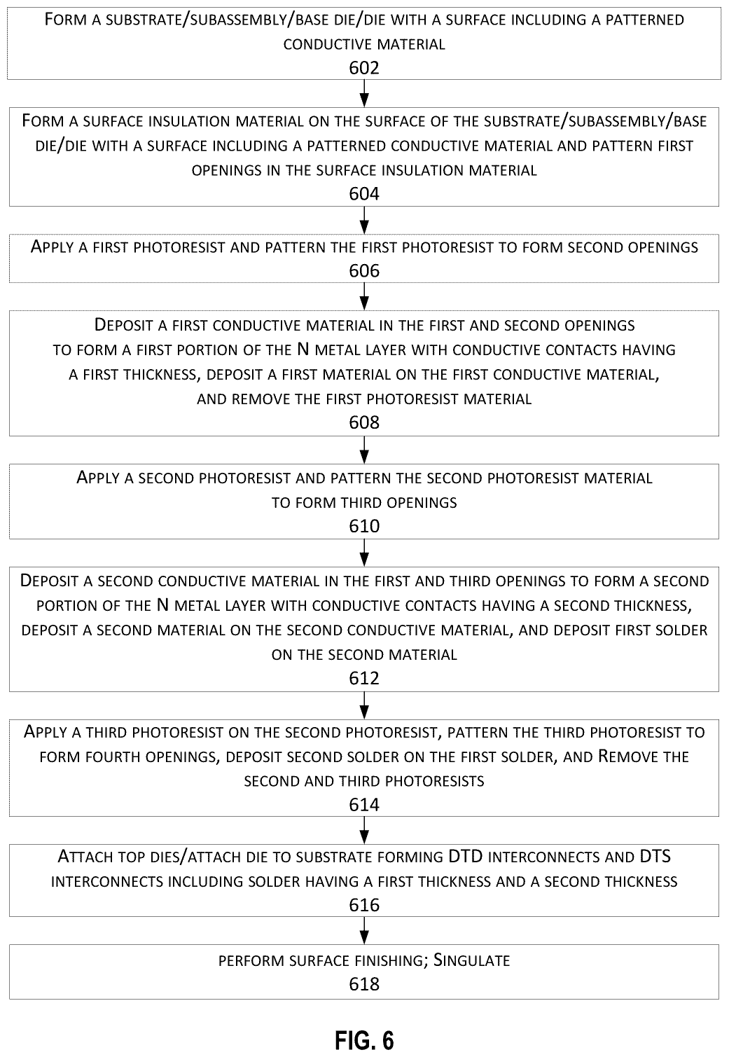

FIG. 6 is a flow diagram of an example process for manufacturing a microelectronic assembly, in accordance with various embodiments. At 602, a portion of a substrate (e.g., a portion of the substrate 107 of FIG. 1A), a multi-layer die subassembly (e.g., a portion of the multi-layer die subassembly 104 of FIG. 2A), a base die (e.g., a portion of the base die 103 of FIG. 3A), or a die (e.g., a die 114-2, 114-3 of FIG. 4A) is formed having a patterned conductive material at a surface, for example, conductive contacts of N−1 metal layer of substrate 107.

At 604, a surface insulation material 117 may be formed on a top surface of the patterned conductive material, and the surface insulation material 117 may be patterned to form first openings 119A. The first openings 119A in the surface insulation material 117 may be formed by mechanical patterning, laser patterning, dry etch patterning, or lithographic patterning techniques.

At 606, a first photoresist 512-1 may be applied to a top surface of the surface insulation material 117 and lithographically patterning to form second openings 119B.

At 608, a first conductive material, such as copper, may be deposited in the first and second openings 119A, 119B to form a first portion of the N metal layer (e.g., conductive contacts 125, 126 having a first thickness 191), a first material 118 may be deposited on the first conductive material, and the first photoresist may be removed. The first conductive material and the first material 118 may be deposited using any suitable technique, such as electroless plating or electrolytic plating.

At 610, a second photoresist 512-2 may be applied to a top surface of the assembly and lithographically patterned to form third openings 119C.

At 612, a second conductive material, such as copper, may be deposited in the first and third openings 119A, 119C to form a second portion of the N metal layer (e.g., conductive contacts 128, 129 having a second thickness 192), a second material 116 may be deposited on a top surface of the second conductive material, and a first solder 145 may be deposited on a top surface of the second material 116. The second portion of the N metal layer, the second material 116, and the first solder 145 may be deposited using any suitable technique, such as electroless plating or electrolytic plating.

At 614, a third photoresist 512-3 may be applied on the second photoresist 512-2 and lithographically patterned to form fourth openings 119D, a second solder 145 may be deposited on the first solder 145 to increase a thickness (e.g., a z-height) of the first solder 145 at a top surface of conductive contacts 128, and the second and third photoresists 512-2, 512-3 may be removed. The second solder 145 may be deposited using any suitable technique, such as electroless plating or electrolytic plating.

At 616, dies 114-2, 114-3 may be attached to the substrate 107, multi-layer die subassembly 104, or base die 103 by forming DTD interconnects 130 and DTS interconnects 140, where the DTD interconnects 130-1 and DTS interconnects 140-1 include solder 145 having a first thickness 195 and DTD interconnects 130-2 and DTS interconnects 140-2 include solder 145 having a second thickness 197.

At 618, finishing operations may be performed on the bottom surface of the assembly, such as depositing solder resist, depositing solder on a bottom surface (e.g., at the first surface 170-1) of conductive contacts of N−4 metal layer, and coupling to a package substrate 102 via STPS interconnects 150, similar to the microelectronic assembly 100 of FIG. 1A. In embodiments where multiple assemblies are manufactured together, the assemblies may be singulated.

The microelectronic assemblies 100 disclosed herein may be used for any suitable application. For example, in some embodiments, a microelectronic assembly 100 may be used to enable very small form factor voltage regulation for field programmable gate array (FPGA) or processing units (e.g., a central processing unit, a graphics processing unit, a FPGA, a modem, an applications processor, etc.) especially in mobile devices and small form factor devices. In another example, the die 114 in a microelectronic assembly 100 may be a processing device (e.g., a central processing unit, a graphics processing unit, a FPGA, a modem, an applications processor, etc.).

The microelectronic assemblies 100 disclosed herein may be included in any suitable electronic component. FIGS. 7-10 illustrate various examples of apparatuses that may include, or be included in, any of the microelectronic assemblies 100 disclosed herein.

FIG. 7 is a top view of a wafer 1500 and dies 1502 that may be included in any of the microelectronic assemblies 100 disclosed herein (e.g., as any suitable ones of the dies 114). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 8, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array. In some embodiments, a die 1502 (e.g., a die 114) may be a central processing unit, a radio frequency chip, a power converter, or a network processor. Various ones of the microelectronic assemblies 100 disclosed herein may be manufactured using a die-to-wafer assembly technique in which some dies 114 are attached to a wafer 1500 that include others of the dies 114, and the wafer 1500 is subsequently singulated.

FIG. 8 is a cross-sectional side view of an IC device 1600 that may be included in any of the microelectronic assemblies 100 disclosed herein (e.g., in any of the dies 114). One or more of the IC devices 1600 may be included in one or more dies 1502 (FIG. 7). The IC device 1600 may be formed on a die substrate 1602 (e.g., the wafer 1500 of FIG. 7) and may be included in a die (e.g., the die 1502 of FIG. 7). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, Ill-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 7) or a wafer (e.g., the wafer 1500 of FIG. 7).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a PMOS or a NMOS transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group Ill-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 8 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 8. Although a particular number of interconnect layers 1606-1610 is depicted in FIG. 8, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 8. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 8. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 8, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die (e.g., like the die 114-1), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die (e.g., like the die 114-1), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

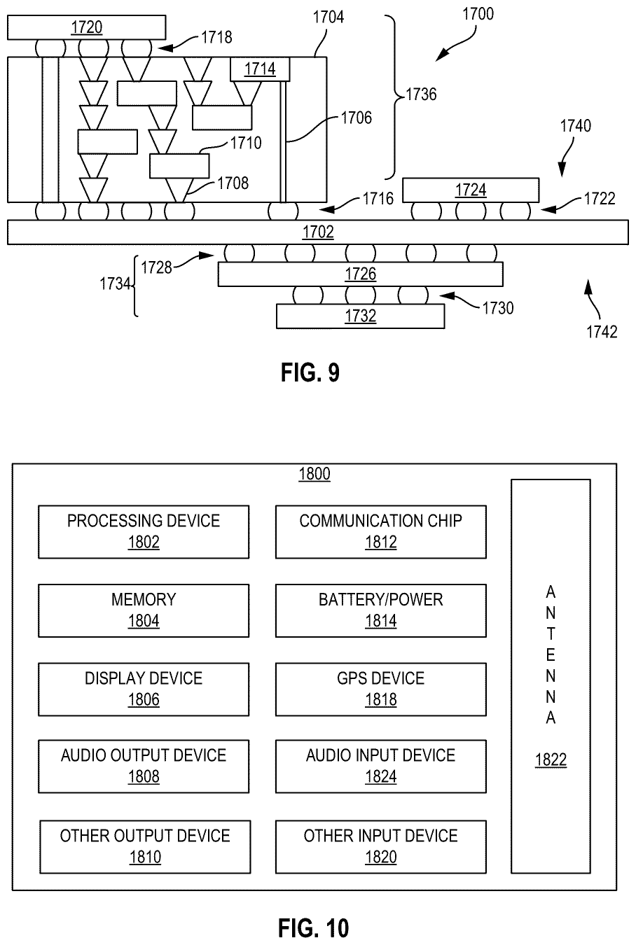

FIG. 9 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 7), an IC device (e.g., the IC device 1600 of FIG. 8), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 9, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group Ill-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 10 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 10, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following paragraphs provide various examples of the embodiments disclosed herein.

Example 1 is a microelectronic assembly, including a substrate having a surface, the surface including: a first conductive contact having a first thickness; and a second conductive contact having a second thickness different than the first thickness, the second conductive contact including a solder material on a top surface; and a bridge component embedded in a dielectric material of the substrate and electrically coupled to the first and second conductive contacts at the surface of the substrate.

Example 2 may include the subject matter of Example 1, and may further specify that the first thickness is greater than the second thickness.

Example 3 may include the subject matter of Examples 1 or 2, and may further specify that the first thickness is between 5 microns and 50 microns.

Example 4 may include the subject matter of any of Examples 1-3, and may further specify that the second thickness is between 2 microns and 35 microns.

Example 5 may include the subject matter of any of Examples 1-4, and may further specify that the first conductive contact includes a first material on a top surface; and wherein the second conductive contact includes a second material between the solder material and the second conductive contact.

Example 6 may include the subject matter of Example 5, and may further specify that the first material includes gold, palladium, nickel, an organic surface protection layer, or a combination thereof.

Example 7 may include the subject matter of Example 5, and may further specify that the second material includes nickel, cobalt, iron, or a combination thereof.

Example 8 may include the subject matter of Example 5, and may further specify that a thickness of the second material is between 1 micron and 8 microns.

Example 9 may include the subject matter of any of Examples 1-8, and may further include a first microelectronic component having a third conductive contact electrically coupled, by a first interconnect, to the first conductive contact, wherein the first interconnect includes solder having a thickness between 2 microns and 35 microns; and a second microelectronic component having a fourth conductive contact electrically coupled, by a second interconnect, to the second conductive contact, wherein the second interconnect includes solder having a thickness between 5 microns and 50 microns.

Example 10 may include the subject matter of Example 9, and may further specify that the first microelectronic component includes memory, a processing die, a radio frequency chip, a power converter, a network processor, a workload accelerator, a voltage regulator die, or a security encryptor.

Example 11 may include the subject matter of Example 9, and may further specify that the bridge component is one of a plurality of bridge components.

Example 12 may include the subject matter of Example 9, and may further specify that the first microelectronic component is one of a plurality of first microelectronic components.

Example 13 may include the subject matter of Example 9, and may further specify that the second microelectronic component is one of a plurality of second microelectronic components.

Example 14 may include the subject matter of Example 9, and may further specify that the surface of the substrate further includes a fifth conductive contact and the first microelectronic component is electrically coupled to the fifth conductive contact, and the microelectronic assembly and may further include a conductive pillar through the dielectric material of the substrate and electrically coupled to the fifth conductive contact.

Example 15 may include the subject matter of any of Examples 1-14, and may further specify that the surface of the substrate is a second surface, the substrate further including a first surface opposite the second surface, and the microelectronic assembly further including a package substrate electrically coupled to the second surface of the substrate.

Example 16 may include the subject matter of any of Examples 1-15, and may further specify that the substrate further includes a core and through core vias.

Example 17 may include the subject matter of any of Examples 1-16, and may further specify that the bridge component includes a first surface and an opposing second surface and is embedded in the dielectric material of the substrate with the second surface electrically coupled to the second and third conductive contacts at the surface of the substrate; and wherein the substrate further includes a conductive material at the first surface of the bridge component.

Example 18 may include the subject matter of Example 17, and may further specify that the substrate further includes an adhesive material between the first surface of the bridge component and the conductive material.

Example 19 is a microelectronic assembly, including a substrate having a surface, the surface including: a first conductive contact having a first thickness; and a second conductive contact having a second thickness different than the first thickness; a first microelectronic component having a third conductive contact electrically coupled, by a first interconnect, to the first conductive contact, wherein the first interconnect includes solder having a thickness between 2 microns and 35 microns; and a second microelectronic component having a fourth conductive contact electrically coupled, by a second interconnect, to the second conductive contact, wherein the second interconnect includes solder having a thickness between 5 microns and 50 microns.

Example 20 may include the subject matter of Example 19, and may further specify that the first thickness is between 5 microns and 50 microns.

Example 21 may include the subject matter of Examples 19 or 20, and may further specify that the second thickness is between 2 microns and 35 microns.

Example 22 may include the subject matter of any of Examples 19-21, and may further include a material between the solder of the second interconnect and the second conductive contact.

Example 23 may include the subject matter of Example 22, and may further specify that the material includes nickel, cobalt, iron, or a combination thereof.

Example 24 may include the subject matter of Example 22, and may further specify that a thickness of the material is between 1 micron and 8 microns.

Example 25 may include the subject matter of any of Examples 19-24, and may further include a bridge component embedded in a dielectric material of the substrate and electrically coupled, by conductive pathways through the substrate, to the first and second conductive contacts at the surface of the substrate.

Example 26 may include the subject matter of any of Examples 19-24, and may further specify that the substrate includes a base die or an interposer.

Example 27 may include the subject matter of any of Examples 19-26, and may further specify that the first microelectronic component includes memory, a processing die, a radio frequency chip, a power converter, a network processor, a workload accelerator, a voltage regulator die, or a security encryptor.

Example 28 may include the subject matter of any of Examples 19-27, and may further specify that the second microelectronic component includes memory, a processing die, a radio frequency chip, a power converter, a network processor, a workload accelerator, a voltage regulator die, or a security encryptor.

Example 29 may include the subject matter of any of Examples 19-28, and may further include a surface insulation material between the surface of the substrate and the first and second conductive contacts.

Example 30 is a microelectronic assembly, including a substrate having a surface, the surface including first conductive contacts and second conductive contacts at a surface of the substrate, wherein the first conductive contacts have a first thickness and the second conductive contacts have a second thickness different than the first thickness; a first microelectronic component having third conductive contacts, wherein respective ones of the third conductive contacts are coupled to respective ones of the first conductive contacts by first interconnects, wherein the first interconnects include solder having a thickness between 2 microns and 35 microns; and a second microelectronic component having fourth conductive contacts, wherein respective ones of the fourth conductive contacts are coupled to respective ones of the second conductive contacts by second interconnects, wherein the second interconnects include solder having a thickness between 5 microns and 50 microns.

Example 31 may include the subject matter of Example 30, and may further specify that the first thickness is greater than the second thickness.

Example 32 may include the subject matter of Examples 30 or 31, and may further specify that the first thickness is between 5 microns and 50 microns.

Example 33 may include the subject matter of any of Examples 30-32, and may further specify that the second thickness is between 2 microns and 35 microns.

Example 34 may include the subject matter of any of Examples 30-33, and may further include a material between the second conductive contacts and the solder of the second interconnects.

Example 35 may include the subject matter of Example 34, and may further specify that the material includes nickel, cobalt, iron, or a combination thereof.

Example 36 may include the subject matter of Example 34, and may further specify that a thickness of the material is between 1 micron and 8 microns.

Example 37 may include the subject matter of any of Examples 30-36, and may further include a surface insulation material between the surface of the substrate and the first and second conductive contacts.

Example 38 may include the subject matter of any of Examples 30-37, and may further include a bridge component embedded in a dielectric material of the substrate and electrically coupled by conductive pathways through the dielectric material of the substrate to some of the first and second conductive contacts at the surface of the substrate.

1. A microelectronic assembly, comprising:
a substrate having a surface, the surface including:
a first conductive contact having a first thickness; and
a second conductive contact having a second thickness different than the first thickness, the second conductive contact including a solder material on a top surface of the second conductive contact; and
a bridge component embedded in a dielectric material of the substrate and electrically coupled to the first and second conductive contacts at the surface of the substrate.

2. The microelectronic assembly of claim 1, wherein the first thickness is greater than the second thickness.

3. The microelectronic assembly of claim 1, wherein the first thickness is between 5 microns and 50 microns.

4. The microelectronic assembly of claim 1, wherein the second thickness is between 2 microns and 35 microns.

5. The microelectronic assembly of claim 1, wherein the first conductive contact includes a first material on a top surface; and wherein the second conductive contact includes a second material between the solder material and the second conductive contact.

6. The microelectronic assembly of claim 5, wherein the first material includes gold, palladium, nickel, an organic surface protection layer, or a combination thereof.

7. The microelectronic assembly of claim 5, wherein the second material includes nickel, cobalt, iron, or a combination thereof.

8. The microelectronic assembly of claim 5, wherein a thickness of the second material is between 1 micron and 8 microns.

9. The microelectronic assembly of claim 1, further comprising:
a first microelectronic component having a third conductive contact electrically coupled, by a first interconnect, to the first conductive contact, wherein the first interconnect includes solder having a thickness between 2 microns and 35 microns; and
a second microelectronic component having a fourth conductive contact electrically coupled, by a second interconnect, to the second conductive contact, wherein the second interconnect includes solder having a thickness between 5 microns and 50 microns.

10. The microelectronic assembly of claim 9, wherein the surface of the substrate further includes a fifth conductive contact and the first microelectronic component is electrically coupled to the fifth conductive contact, and the microelectronic assembly further comprising:
a conductive pillar through the dielectric material of the substrate and electrically coupled to the fifth conductive contact.

11. The microelectronic assembly of claim 1, wherein the surface of the substrate is a second surface, the substrate further including a first surface opposite the second surface, and the microelectronic assembly further including:
a package substrate electrically coupled to the second surface of the substrate.

12. A microelectronic assembly, comprising:
a substrate having a surface, the surface including:
a first conductive contact having a first thickness; and
a second conductive contact having a second thickness different than the first thickness;
a first microelectronic component having a third conductive contact electrically coupled, by a first interconnect, to the first conductive contact, wherein the first interconnect includes solder having a thickness between 2 microns and 35 microns; and
a second microelectronic component having a fourth conductive contact electrically coupled, by a second interconnect, to the second conductive contact, wherein the second interconnect includes solder having a thickness between 5 microns and 50 microns.

13. The microelectronic assembly of claim 12, wherein the first thickness is between 5 microns and 50 microns.

14. The microelectronic assembly of claim 12, wherein the second thickness is between 2 microns and 35 microns.

15. The microelectronic assembly of claim 12, further comprising:
a material between the second conductive contact and the solder of the second interconnect, wherein the material includes nickel, cobalt, iron, or a combination thereof.

16. The microelectronic assembly of claim 12, further comprising:
a bridge component embedded in a dielectric material of the substrate and electrically coupled, by conductive pathways through the substrate, to the first and second conductive contacts at the surface of the substrate.

17. A microelectronic assembly, comprising:
a substrate having a surface, the surface including first conductive contacts and second conductive contacts at a surface of the substrate, wherein the first conductive contacts have a first thickness and the second conductive contacts have a second thickness different than the first thickness;
a first microelectronic component having third conductive contacts, wherein respective ones of the third conductive contacts are coupled to respective ones of the first conductive contacts by first interconnects, wherein the first interconnects include solder having a thickness between 2 microns and 35 microns; and
a second microelectronic component having fourth conductive contacts, wherein respective ones of the fourth conductive contacts are coupled to respective ones of the second conductive contacts by second interconnects, wherein the second interconnects include solder having a thickness between 5 microns and 50 microns.

18. The microelectronic assembly of claim 17, wherein the first thickness is between 5 microns and 50 microns.

19. The microelectronic assembly of claim 17, wherein the second thickness is between 2 microns and 35 microns.

20. The microelectronic assembly of claim 17, further comprising:
a surface insulation material between the surface of the substrate and the first and second conductive contacts.
